(19) United States
(12) Patent Application Publication
(10) Pub. No.: US 2011/0141802 A1
(43) Pub. Date: Jun. 16, 2011

(54) METHOD AND SYSTEM FOR PROVIDING A HIGH DENSITY MEMORY CELL FOR SPIN TRANSFER TORQUE RANDOM ACCESS MEMORY

(75) Inventor: Adrian E. Ong, Pleasanton, CA (US)

(73) Assignee: GRANDIS, INC., Milpitas, CA (US)

(21) Appl. No.: 12/638,902

(22) Filed: Dec. 15, 2009

(51) Int. Cl. G11C 11/14; G11C 7/00

(52) U.S. Cl. 365/171; 365/189.011

(57) ABSTRACT

A method and system for providing a magnetic memory are described. The method and system include providing a plurality of magnetic storage cells, a plurality of bit lines corresponding to the magnetic storage cells, a plurality of word lines corresponding to the magnetic storage cells, and a common voltage plane coupled with the magnetic storage cells. Each of the magnetic storage cells includes at least one magnetic element and at least one selection device coupled with the magnetic element(s). The magnetic element(s) are programmable using at least one write current driven through the magnetic element(s). The common voltage plane is coupled with the memory cells. The write current(s) flow between the common voltage plane, the magnetic element(s), and at least one of the bit lines.

### GOVERNMENT RIGHTS

This invention was made with U.S. Government support under Grant/Contract No. HR0011-09-C-0023 awarded by DARPA. The U.S. Government retains certain rights in this invention.

### BACKGROUND OF THE INVENTION

FIGS. 1-3 depict portions of a conventional spin transfer torque magnetic random access memory (STT-RAM). FIG. 1 is a schematic view of a portion of the STT-RAM 1 including a storage cell 10. FIG. 2 depicts a perspective view of the portion of the conventional STT-RAM 1. FIG. 3 is a plan view of a portion of the conventional STT-RAM. For simplicity, only portions of the conventional STT-RAM depicted in FIG. 3 are labeled. The conventional STT-RAM 1 utilizes spin transfer as a mechanism for switching the state of the magnetic storage cell. The conventional STT-RAM 1 includes a conventional magnetic storage cell 10 including a magnetic element 12 and a selection device 14. The selection device 14 is generally a transistor such as a NMOS transistor and includes a drain 11, a source 13, and a gate that is included the word line 16. Also depicted are a conventional bit line 18 and conventional source line 20 having contacts 19 and 21, respectively. Both the conventional bit line 18 and the conventional source line 20 are typically metal lines. The conventional word line 16 is oriented perpendicular to the bit line 18. The conventional source line 20 is typically perpendicular to the bit line 18. The conventional bit line 18 is connected to the magnetic element 12, while the conventional source line 20 is connected to the source 13 of the selection device 14. Note that for clarity, in FIG. 3 the conventional source line 20 is just shown by an arrow.

The conventional STT-RAM 1 programs the magnetic memory cell 10 by driving a bi-directional current through the cell 10. In particular, the magnetic element 12 is configured to be changeable between high and low resistance states by a current flowing through the conventional magnetic element 12. For example, the magnetic element 12 may be a magnetic tunneling junction (MTJ) or other magnetic structure that may be written using the spin transfer effect. Typically, this is achieved by ensuring that the magnetic element 12 has, for example, a sufficiently small cross-sectional area as well as other features desirable for switching using the spin transfer effect. When the current density is sufficiently large, the current carriers driven through the magnetic element 12 may impart sufficient torque to change the state of the magnetic element 12. When the write current is driven in one direction, the state may be changed from a low resistance state to a high resistance state. When the write current passes through the magnetic element 12 in the opposite direction, the state may be changed from a high resistance state to a low resistance state.

During write operations, the word line 16 is high, which turns on the transistor 14. The conventional bit line 18 or the conventional source line is driven high during writing. The write current flows either from the conventional bit line 18 to the conventional source line 20, or vice versa, depending upon the state to be written to the magnetic memory cell 10. During read operations, the desired conventional bit line 18 is selected the appropriate word line(s) 16 are enabled. Consequently, a read current flows from the conventional bit line 18 to the conventional source line 20.

Although the conventional STT-RAM 1 functions, one of ordinary skill in the art will readily recognize that there are drawbacks for higher density memories. Currently, there is a drive in the memory industry to higher densities. The density of the storage cells 10 is driven in part by the critical dimension, f. The critical dimension is the smallest dimension that can be fabricated using conventional photolithography. Currently, the critical dimension, f, in the conventional STT-RAM 1 is forty-five nanometers. As can be seen in FIG. 3, for such a critical dimension, the current minimum cell area is 6f². In a minimum-cell size configuration, the bit line 18 is oriented perpendicular to source line 20 in order to allow for sufficient room to make contact to both the transistor 14 and the magnetic element 12. Although the minimum cell size shown is possible, layout of the cell and electronics coupled to the transistor 14 and magnetic element 14 is difficult. Consequently, an improved mechanism for providing a high density STT-RAM is desired.

### BRIEF SUMMARY OF THE INVENTION

A method and system for providing a magnetic memory are described. The method and system include providing a plurality of magnetic storage cells, a plurality of bit lines corresponding to the magnetic storage cells, a plurality of word lines corresponding to the magnetic storage cells, and a common voltage plane coupled with the magnetic storage cells. Each of the magnetic storage cells includes at least one magnetic element and at least one selection device coupled with the magnetic element(s). The magnetic element(s) are programmable using at least one write current driven through the magnetic element(s). The common voltage plane is coupled with the memory cells. The write current(s) flow between the common voltage plane, the magnetic element(s), and at least one of the bit lines.

According to the method and system disclosed herein, the present invention provides a magnetic memory which may be integrated at higher density.

### BRIEF DESCRIPTION OF SEVERAL VIEWS OF THE DRAWINGS

FIG. 1 is a schematic diagram of a portion of a conventional magnetic memory employing the spin transfer effect.

FIG. 2 is a diagram depicting a perspective view of a portion of a magnetic memory array employing the spin transfer effect.

FIG. 3 is a diagram of a plan view of portion of a conventional magnetic memory employing the spin transfer effect.

FIG. 4 is a diagram of an exemplary embodiment of a portion of a magnetic memory employing the spin transfer effect and having a common voltage plane.

FIG. 5 is a diagram of another exemplary embodiment of a portion of a magnetic memory employing the spin transfer effect and having a common voltage plane.

FIG. 6 is a diagram of another exemplary embodiment of a portion of a magnetic memory employing the spin transfer effect and having a common voltage plane.

FIG. 7 is a plan view of an exemplary embodiment of a portion of a magnetic memory employing the spin transfer effect and having a common voltage plane.

FIG. 8 is a plan view of another exemplary embodiment of a portion of a magnetic memory employing the spin transfer effect and having a common voltage plane.

FIG. 9 is an exemplary embodiment of a hierarchical memory using a common voltage plane.

FIG. 10 is another exemplary embodiment of a hierarchical memory employing a common voltage plane.

FIG. 11 depicts an exemplary embodiment of a pre-amplifier for use with a hierarchical memory.

FIG. 12 depicts an exemplary embodiment of a write driver for use with a hierarchical memory.

FIG. 13 depicts an exemplary embodiment of a method for providing a magnetic memory employing the spin transfer effect.

### DETAILED DESCRIPTION OF THE INVENTION

The present invention relates to magnetic memories. The following description is presented to enable one of ordinary skill in the art to make and use the invention and is provided in the context of a patent application and its requirements. Various modifications to the preferred embodiments and the generic principles and features described herein will be readily apparent to those skilled in the art. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments. The embodiments will be described with respect to systems and/or devices having certain components. However, the systems and/or devices may include more or less components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein. Further, for clarity, the drawings are not to scale

A method and system for providing a magnetic memory are described. The method and system include providing a plurality of magnetic storage cells, a plurality of bit lines corresponding to the magnetic storage cells, a plurality of word lines corresponding to the magnetic storage cells, and a common voltage plane coupled with the magnetic storage cells. Each of the magnetic storage cells includes at least one magnetic element and at least one selection device coupled with the magnetic element(s). The magnetic element(s) are programmable using at least one write current driven through the magnetic element(s). The common voltage plane is coupled with the memory cells. The write current(s) flow between the common voltage plane, the magnetic element(s), and at least one of the bit lines

FIG. 4 is a diagram of an exemplary embodiment of a portion of a magnetic memory 100 employing the spin transfer effect. For simplicity, only a portion of the magnetic memory 100 is shown. The magnetic memory 100 is preferably a STT-RAM 100 and will thus be described as such. In some embodiments, the STT-RAM 100 may be organized in a hierarchical manner, as described below. The magnetic memory 100 includes a number of magnetic storage cells 110, of which only one is shown in FIG. 4.

The storage cell 110 includes a magnetic element 112 and a selection device 114. Although only one magnetic element 112 and one selection device 114 are shown, more than one magnetic element 112 and/or more than one selection device might be used. For example, two magnetic elements 112 might be used and/or two selection devices 114 might be used. In such an embodiment, the magnetic elements 112 might be configured in a differential scheme. The magnetic element 112 may be a magnetic tunneling junction configured to be written using the spin transfer effect. In other embodiments, the magnetic element 112 might be a dual magnetic tunneling junction, a spin valve, a dual spin valve, or other analogous structure. However, in other embodiments, the magnetic element 112 may utilize another mechanism for storing data. However, in such embodiments, current is still used to write to the element 112. In the embodiments described herein, the selection device 114 is a selection transistor and will be termed such. The selection transistor 114 thus includes a source 111, drain 113, and gate 115. However, in other embodiments, another device might be used.

The STT-RAM 100 also includes bit line 118, a word line 116, and a common voltage plane 120. In the embodiment shown in FIG. 4, the bit line 118 and word line 116 are coupled with the selection transistor 114. More specifically, the bit line 118 is coupled to the drain 113, while the word line 116 is shown coupled to the gate 115. In some embodiments, the word line 116 is a polysilicon line that also forms the gate 115 of the selection transistor 114 in each storage cell 110 along the word line 116. One end of the magnetic element 112 is coupled with the source 111 of the selection transistor 144. Thus, read and write currents may flow through the bit line 118, selection transistor 114, and magnetic element 112.

In the embodiment shown in FIG. 4, the common voltage plane 120 is coupled with the other end of the magnetic element 112. The magnetic element 112 is thus connected between the selection transistor 114 and the common voltage plane 120. The common voltage plane 120 is so termed because the plane is common to all or at least a significant portion of the storage cells 110 in the STT-RAM 100 which may be along different word lines 116 and different bit lines 118. In some embodiments, all of the storage cells 110 in the STT-RAM 100 are connected via the common plane 120. In other embodiments, the STT-RAM 100 may be arranged in tiles and/or banks. In such an embodiment, storage cells 110 a tile and/or bank may share the common voltage plane 120. The common voltage plane 120 may be a sheet of metal. In other embodiments, other conductive materials, such as polysilicon, might be used for the common voltage plane. In some embodiments, the common voltage plane 120 lies over the STT-RAM array. Thus, the magnetic element 112 and the bit line 118 may reside between the common voltage plane 120 and the selection transistor 114 or an underlying substrate.

FIG. 5 is a diagram of another exemplary embodiment of a portion of a magnetic memory 100′ employing the spin transfer effect. For simplicity, only a portion of the magnetic memory 100′ is shown. The magnetic memory 100′ is analogous to the magnetic memory 100 depicted in FIG. 4, the magnetic memory 100′ thus includes storage cells 110′, word line 116′, bit line 118′, and common voltage plane 120′ analogous to the storage cells 110, word line 116, bit line 118, and common voltage plane 120, respectively. The storage cells 110′ includes a magnetic element 112′ and a selection device 114′ having a source 111′, a drain 113′, and a gate 115′ that are analogous to the selection device 114 having the source 111, the drain 113, and the gate 115. Although only one magnetic element 112′ and one selection device 114′ are shown, more than one magnetic element 112′ and/or more than one selection device might be used.

The STT-RAM 100′ also includes bit line 118′, word line 116′, and common voltage plane 120′. In the embodiment shown in FIG. 5, the word line 116′ is coupled with the gate 115′ of the selection transistor 114′. In some embodiments, the word line 116′ is a polysilicon line that also forms the gate 115′ of the selection transistor 114′ in each storage cell 110′ along the word line 116′. One end of the magnetic element 112 is coupled with the drain 113′ of the selection transistor 114′. The bit line 118′ is coupled with the other end of the magnetic element 112′. In the embodiment shown in FIG. 5, the common voltage plane 120′ is coupled with the source 111′ of the selection transistor 112′. To the extent that the magnetic element 112′ is connected between the drain 112′ of the selection transistor 112′ and the bit line 118′, the STT-RAM 100′ is also analogous to the conventional STT-RAM 10.

As discussed above, an STT-RAM could include storage cells having multiple magnetic elements and/or multiple selection devices. For example, FIG. 6 depicts a memory 100″ having a storage cell 110″ that is a combination of the memory cells 110 and 110′. In such an embodiment, the two transistor 114/114′-two magnetic element 112/112′ storage cell 110″ could be driven using a single word line that is connected to both selection devices 114 and 114′. In such an embodiment, each bit is now represented by true (e.g. magnetic element 112) and compliment (e.g. magnetic element 112′) data. During a write operation, bit lines 118 and 118′ are driven in opposite directions. Typically, common plane voltage coupled to the common voltage plane 120/120′ is half way in between a supply voltage Vdd (a logical “1”) and ground (ground is logic “0”). The writing voltage across the both magnetic elements 112 and 112′ and selection devices 114 and 114′ are opposite and equal. For example, the writing voltages for magnetic element 112/selection device 114 and magnetic element 112′/114 are +Vdd/2 and −Vdd/2, respectively. During a read operation, both bit lines 118 and 118′ can be forced to ground, while the common plane voltage 120/120′ is set to a read voltage. The read voltage may be different from the write voltage. For example, the read voltage may be lower than (a fraction of) half Vdd to reduce read disturb. The read voltage and write voltage may be driven from multi-voltage generator circuit. To adjust the read voltage, and thus read current, the voltages to the common planes 120/120′ and bit lines 118/118′ may be changed. For example, common voltage planes 120/120′ could be driven to a lower voltage, or bit lines 118/118′ may be driven slightly above ground.

Referring to FIGS. 4, 5, and 6, the common voltage plane 120/120′ is biased at a particular common voltage. For example, the common voltage plane 120/120′ may be connected to the common voltage via a metal bus. The common voltage may be driven from an external source, for example via external pads. The common voltage might be generated internally via a voltage generator. In some embodiments, this common voltage is a fraction of the external supply voltage. For example, the common voltage plane 120/120′ may be biased at a voltage somewhere between the external chip power, V_{dd}, and ground. In some such embodiments, the common voltage may be a fraction of the array supply voltage, V_{dda}. For example, the common voltage may be one-half of the supply voltage. In other embodiments, the common voltage is another fraction of the supply voltage. In some embodiments, the common voltage of the common plane 120/120′ is constant throughout operation of STT-RAM 11. Thus, the common plane 120/120′ need not switch voltages to program the magnetic elements 112/112′ to different states.

In operation, data may be read from the magnetic element 112/112′ by driving a read current through the magnetic element 112/112′ while the selection transistor 114/114′ is enabled. This read current is insufficient in magnitude to write to the magnetic element 112/112′. The read current may be driven from the bit line 118/118′ to the common plane 120/120′ or vice versa.

To write to the magnetic element 112/112′, a larger, write current is driven through the magnetic element 112. In most STT-RAMS, and may be the case with the STT-RAMS 100/100′, the magnetic element 112/112′ are magnetic tunneling junctions or spin valves having at least one free layer and at least one pinned layer. In some embodiments, the pinned layer is coupled to the selection transistor 114/114′, while the free layer is coupled to the source line 120/bit line 118′. To program the magnetic element 112 to a first state (free and pinned layer magnetizations programmed from parallel to antiparallel), e.g. a logical “1”, the bit line 118 may be biased high with respect to the common voltage of the common plane 120 while the selection transistor 114 is enabled. To program the magnetic element 112 to a second state (e.g. free and pinned layer magnetizations programmed from an antiparallel state to a parallel state), the bit line 118 may be biased low with respect to the common voltage while the selection transistor 114 enabled. For the magnetic element 112′ to be programmed to a logical “1” (free and pinned layer magnetizations programmed from parallel antiparallel), the line 118′ is driven low with respect to the common voltage of the common plane 120′ while the selection device 114′ is enabled. To write the magnetic element 112′ to the second state (e.g. free and pinned layer magnetizations programmed from an antiparallel state to a parallel state), the bit line 118′ may be biased high with respect to the common voltage with the selection transistor 114′ enabled. In some embodiments, for writing a logical “1”/“0” the bit line 118/118′ may be biased at the supply voltage while the common plane 120/120′ is biased at half of the supply voltage. Thus, write current flows from the bit line 120/120′, through the magnetic element 112/112′ and the selection transistor 114/114′ and to the common voltage plane 120/120′. For the storage cell 110, the write current flows through the selection transistor 114 prior to the magnetic element 112. For the storage cell 110′, the write current flows through the magnetic element 112′ prior to the selection transistor 114′. As discussed above, to write a “0”/“1”, the bit line 118/118′ is biased low with respect to the common voltage of the common plane 120/120′. In some embodiments, the bit line 118/118′ is biased at zero or below 0 v (e.g. −0.4 volts) with respect to the common voltage of the common plane 120/120′. In some such embodiments, the common voltage is one half the supply voltage, for example approximately 0.5 volt for a 1.0 volt supply voltage. In programming the magnetic element 112/112′ to the second state, a write current flows from the common voltage plane 120/120′ to the magnetic element 112/112′ and selection transistor 114/114′, and to the bit line 118/118′. For the storage cell 110, the write current flows through the selection transistor 114 after the magnetic element 112. For the storage cell 110′, the write current flows through the magnetic element 112′ after the selection transistor 114′. In some embodiments, the bit line 118/118′ is driven above Vdd to boosted voltage, Vpp (e.g. Vdd+Vt or Vdd+0.1 v) in a write operation. This boosted voltage may, for example, be generated from an on-chip high voltage pump or from an external high voltage input pad (or pads). In some embodiments where bit-lines are boosted to Vpp or driven to 0 v (true and compliment data), the common plane 120/120′ maybe set to half Vpp (Vpp/2). In some embodiments using the circuit shown in FIG. 6, the common voltage generator or driver maybe temporary disabled or tri-stated. This allows Vdd (or Vpp) in one bit-line 118′/118 to flow through both the magnetic element 112/112′ to the other bit-line 118/118′. Thus, one magnetic element is written from a parallel to an antiparallel state, while the other is programmed from the antiparallel to the parallel state. In this embodiment, the voltage generator may be used to pre-charge the common plane 120′ to the common voltage. This assists in the writing operation, which requires no current from the common voltage generator.

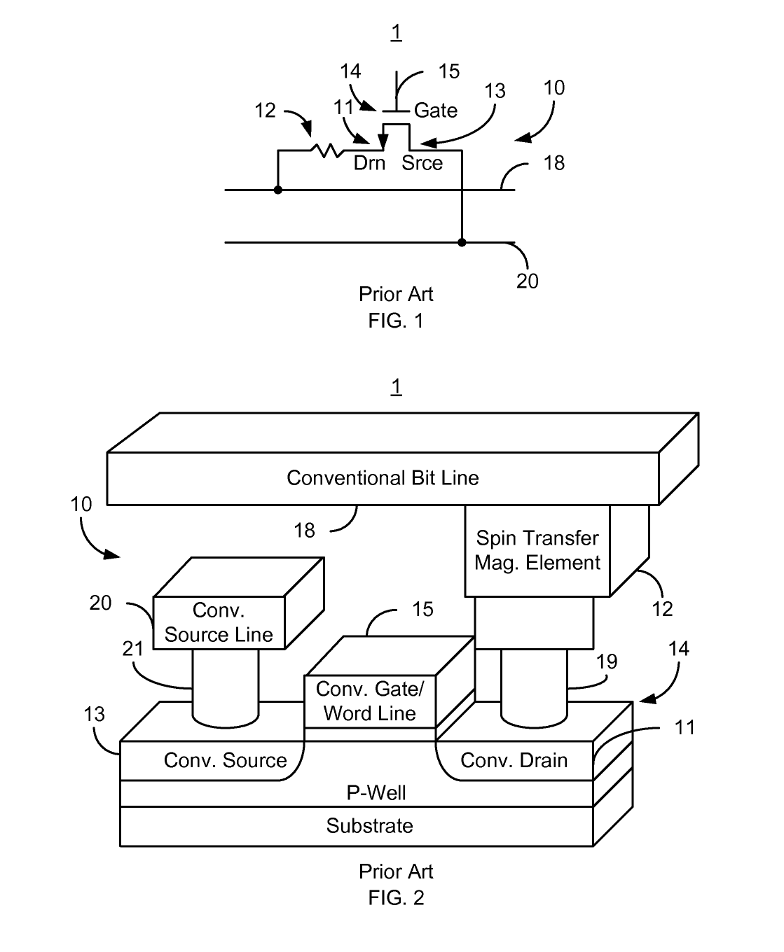

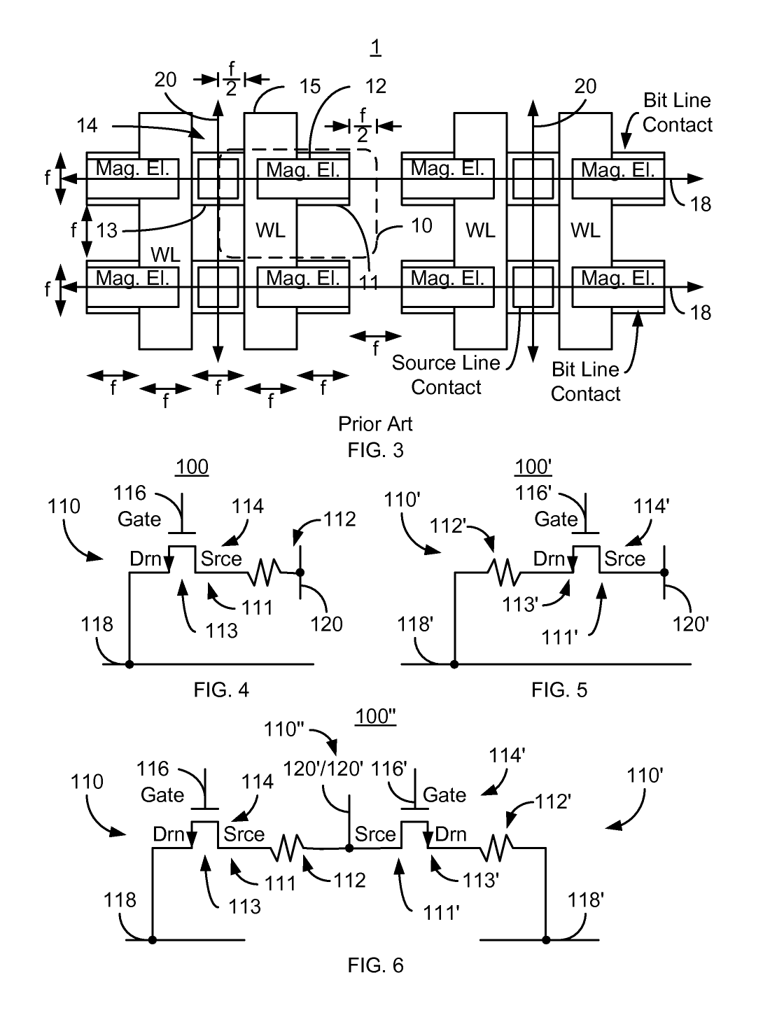

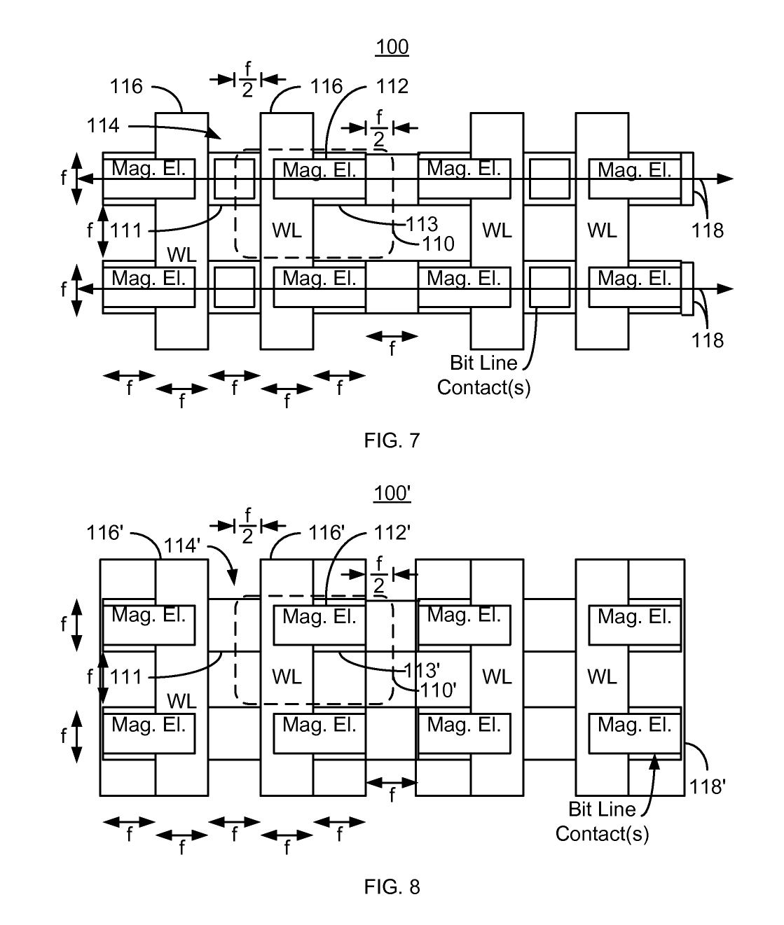

Thus, the magnetic elements 112/112′ may be written to and read from. Because the common voltage plane 120/120′ is used, the line 20 or line 18 of the conventional STT-RAM 1 depicted in FIGS. 1-3 may be omitted. Instead of making contact to a single line for each storage cell, contact may be made to a plane. As such, layout of the storage cell 110/110′/110″ becomes simpler. For example, FIGS. 7 and 8 depict plan views of the STT-RAM 100 and 100′, respectively, in which the simplified layout may be seen. Note that the STT-RAM 100′ shown in FIG. 8 has its bit lines 118′ parallel to the word lines 116′. Further processing of the common plane 120/120′does not require photolithography to define source or other lines in the common plane 120/120′. Fabrication is thus simplified and made less expensive. Selection circuitry for selecting the appropriate source lines, as well as the source lines themselves, may also be omitted as the common plane 120/120′ is used. As a result, layout of circuitry for the STT-RAM 100/100′/100″ that is not shown in FIGS. 4-6 may be simplified. In addition, because circuitry may be omitted and layout improved, a space savings may be achieved. For example, in the conventional STT-RAM 1, the conventional bit lines 18 are perpendicular to the conventional source lines 20. As a result, either the source line 20 or the bit line 18 would be re-routed together to allow circuitry to be in one location. Alternatively, drivers could be in opposing locations. However, this means the data-in signals must be driven to both locations. The conventional source line 20 and the conventional bit line 18 can be parallel. This architecture simplifies the read and write circuitry, allowing the lines 18 and 20 to be laid out in the same location. However, the lines 18 and 20 can only be laid out in parallel if the there is sufficient space in a conventional storage cell 10 to make contact. The width of the active area is at least twice the size of the contacts 19 and 21. This would require the width of the conventional selection transistor 12 to be greater or equal than 2F. This may make the smallest 6F² cell 10 shown in FIG. 1 impossible with current process technology. In contrast, in the STT-RAM 100/100′ the word lines 116/116′ and bit lines 118/118′ may be perpendicular and the bit lines 118/118′ driven with single circuitry. Consequently, use of the common source plane may also reduce the total area occupied by the STT-RAM 100/100′/100″. Note that in another embodiment, the bit lines 118/118′ may be perpendicular to the word lines 116/166′. However, in such an embodiment, the common plane 120/120′ may have multiple apertures therein to allow contact to be made to the selection devices 114/114′ while maintaining a smaller storage cell size, for example on the order of 6f².

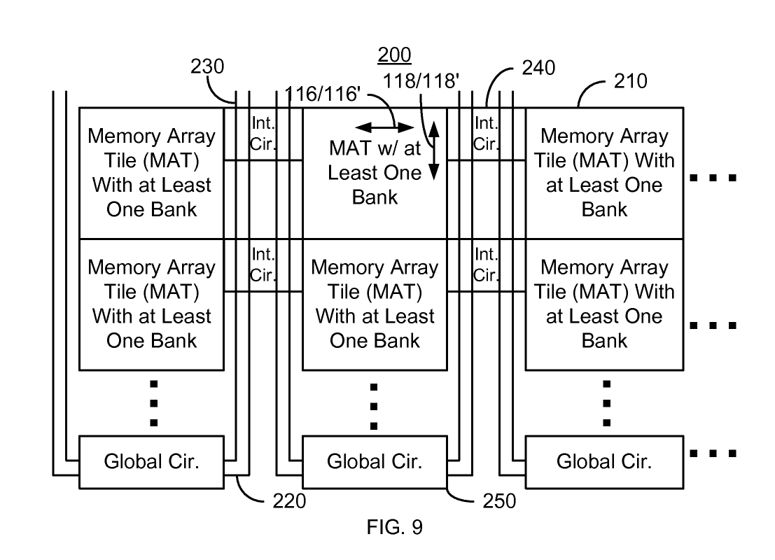

FIG. 9 is an exemplary embodiment of a hierarchical memory 200 using a common voltage plane. The hierarchical memory 200 includes memory array tiles (MATs) 210, global circuitry bit lines 220, global write lines 230, intermediate circuitry 240, and global circuitry 250. Although particular numbers of global bit lines 220, global write lines 230, intermediate circuitry 240, and global circuitry 250 are shown, As can be seen in FIG. 9, the combination of MAT 210, global bit lines 220, global write lines 230, intermediate circuitry 240, and global circuitry 250 may be repeated to scale the magnetic memory 100 up to provide storage of a greater amount of data. For example, in the embodiment shown in FIG. 9, the intermediate circuitry 240 controls read and write operation(s) in the MAT 210 to its left and/or right. In the hierarchical memory 200, each MAT 210 includes an array of storage cells such as the storage cells 110/110′. Thus, the MATs 210 employ a common voltage plane such as the common voltage plane 120/120′. Separate common voltage planes 120/120′ may be provided for each MAT 210 or a single common voltage plane 120/120′ may be provided for more than one MAT 210. For example, a portion of the MATs 210 or all of the MATs 210 may share a common voltage plane 120/120′. For simplicity, the storage cells 110/110′ and their constituents as well as the common voltage plane 120/120′ are not explicitly shown in FIG. 9.

As discussed above, the intermediate circuitry 240 controls read and/or write operations in corresponding MAT(s) 210. The intermediate circuitry 240 includes drive/sense circuitry (not shown in FIG. 9). For example, the intermediate circuitry 240 includes intermediate read drivers for controlling read operations in the corresponding MAT(s). Similarly, the intermediate circuitry 240 may also include intermediate write drivers for driving write operations the corresponding MAT(s). Further local decoding circuitry for selecting between the MAT(s) and for selecting one or more storage cell 110/110 in the selected MAT(s) is also included in the intermediate circuitry 240.

Each global bit line 220 corresponds to a portion of the plurality of MATs 210. The global bit line 220 for the MATs 210 is coupled with a portion of the bit lines 118/118′ for that corresponding portion of the MATs 210. Similarly, each global write line 230 corresponds to a portion of the MATs 210. The global write line 230 is coupled the with word lines 116/1116′ of the corresponding portion of the MATs 210. The global circuitry 250 selects and drives one or more of the global bit lines 220 and global write lines 230 for read and write operations.

Because of the use of the common voltage plane 120/120′, the memory 200 shares the benefits of the memories 100/100′ described above. In addition, the memory 200 is organized in a modular, hierarchical architecture. As a result, larger memories may be built by adding one or more of the modules 210, 220, 230, 240, and 250. The memory 200 is thus scalable to larger, more dense memories. For example, the memory 200 might be scalable to gigabit (Gb) densities or beyond. Further, the global bit lines 220 and global write lines 230 may have a lower resistance than the bit lines 118/118′ and write lines 116/116′ within each MAT 210. In some embodiments, this may be achieved by forming the global lines 220 and 230 in the metal 3 layer. Thus, the parasitic resistance may be reduced and/or limited to the MATs 210. Array efficiency may thus be increased with little performance impact. Short write times, for example on the order of ten nanoseconds with a write energy of less than one picoJoule and small read access times, for example of less than 5 ns, might also be achieved in some embodiments. Sense amplifiers may be located in the global circuitry 250 and thus de-coupled from the local bit lines 118/118′. Multiple MATs may also share a set of global sense amplifiers and global write drivers in the global circuitry 250. In some embodiments, the array size may thus be reduced, for example by 40% over a memory having the same size but using localized sense amplifiers. Use of the intermediate circuitry 240 for sensing signals, driving currents, and decoding within the MATs may reduce read and/or write penalties. Consequently, the memory 200 may be usable in higher density memories, such as high density STT-RAM. Thus, the benefits of STT-RAM, such as lower power consumption, lower cost, and non-volatility may be scaled to higher density memories.

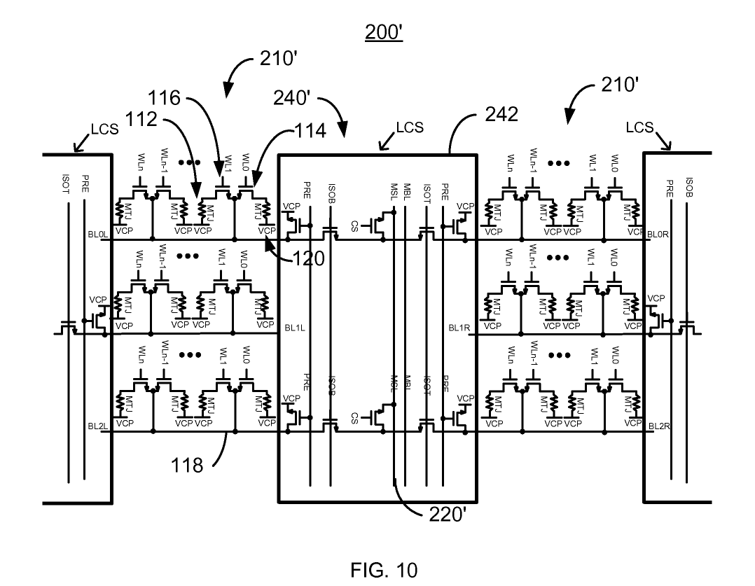

FIG. 10 is another exemplary embodiment of a hierarchical STT-RAM 200′ employing a common voltage plane. The hierarchical STT-RAM 200′ is analogous to the hierarchical STT-RAM shown in FIG. 9. Thus, corresponding portions of the STT-RAM 200′ are labeled similarly to the STT-RAM 200. In particular, FIG. 10 depicts an embodiment of a portion of the local decoding, local column select, or pre-charge circuitry 242 that may be considered part of the intermediate circuitry 240′. Also shown is the storage cell 110 including selection transistor 112 and magnetic element 114. The bit lines 118, the common voltage plane 120, and word lines 116 for MATs 210′ are also shown. Although shown in the context of the cell 110 and corresponding memory 100, the STT-RAM 200′ may incorporate the storage cell 110′ and remaining portions of the memory 100′ in other embodiments. Bit lines 118 are pre-charged to the common voltage (the same voltage as the common plane 120) when not activated. Since the bit lines 118 and the common plane 120 are at the same voltage during stand-by or pre-charge cycle (the word lines 116 are off as well), there may be zero leakage current in the STT-RAM 200′.

As can be seen in FIG. 10, because of the use of the common voltage plane 120/120′, separate column selection circuitry for source lines may be omitted from the local column select 242. Instead, the local column select circuitry 242 merely selects the appropriate bit line. Thus, selection transistors for source lines as well as global lines for the source lines may be omitted. Consequently, the local column select circuitry may be simplified. As a result, layout may be made easier, fabrication improved, and cost and real estate savings may be increased.

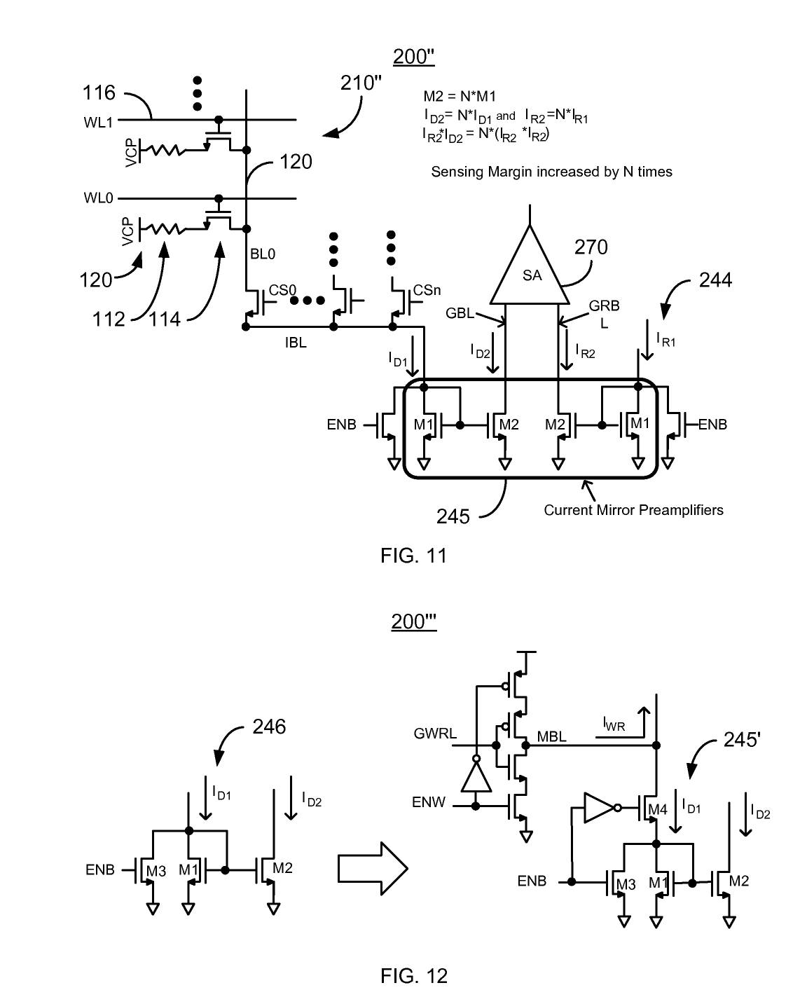

FIG. 11 depicts an exemplary embodiment of a portion of a hierarchical memory 200″ employing a common voltage plane. The hierarchical STT-RAM 200″ is analogous to the hierarchical STT-RAMS shown in FIGS. 9-10. Thus, corresponding portions of the STT-RAM 200″ are labeled similarly to the STT-RAMS 200/200′. In particular, FIG. 11 depicts an embodiment of a portion of the read circuitry 244 that may be considered part of the intermediate circuitry 240/240″. Also shown is the storage cell 110 including selection transistor 112 and magnetic element 114. The bit lines 118, the common voltage plane 120, and word lines 116 for MAT 210″ are also shown. Although shown in the context of the cell 110 and corresponding memory 100, the STT-RAM 200″ may incorporate the storage cell 110′ and remaining portions of the memory 100′ in other embodiments.

More specifically, FIG. 11 depicts read circuitry 244 in the context of other portions of the memory 200″, including decoding circuitry, for example as shown in the column select transistors receiving column select signals CS0-CSn. The intermediate circuitry 240/240′/240″ may include passgate(s) and/or preamplifiers. The read circuitry 244 includes a preamplifier 245. In the embodiment shown, the preamplifier 245 is a current mirror preamplifier, using transistor pairs M1 and M2 to form the current mirror. In the current mirror, M2 equals N*M1, where N is greater than one. Therefore, the current mirror preamplifier 245 outputs an amplified current that is N times the input read current. Stated differently, the preamplifier 245 amplifies the read signal from the magnetic elements 112 by a factor of N. Thus, a lower read current may be used within the MATs 210″. More specifically, the transistors M1 may have a width designed to provide a small read current that is well under the switching current of the magnetic element(s) of the storage cell. Thus, a read operation may be performed without disturbing the state of the storage cells in the MAT(s) 210/210′/210″. In addition, power dissipation by read current carried by higher resistance bit lines 118 may be reduced. Using M2 transistors having widths designed to provide sufficient amplification allows for a higher output current. Thus, more robust sensing is achieved. Note that sense amp current path is decoupled from the current path of the magnetic element. The preamplifier 245 thus amplifies the read current from the MAT(s) 110/110′ and may drive the current to global circuitry 250/250′. More specifically, in the embodiment shown, the amplified current may be provided to sense amplifier 270 that may be part of the global circuitry 250′.

The magnetic memory 200″ may share the benefits of the memories 100, 100′, 100″, 200, and 200′. In addition, because of the use of the preamplifier 245, there may be little or no read penalty. More specifically, as discussed above, a lower read current may be used within the MATs 210/210′/210″, amplified by the preamplifier 245, and the amplified current may be provided to the sense amplifier 270 for determination of the state of the storage cell being read. Consequently, performance may be improved.

FIG. 12 depicts an exemplary embodiment of a portion of a hierarchical memory 200″′ employing a common voltage plane. The hierarchical STT-RAM 200″′ is analogous to the hierarchical STT-RAMS 200/200′/200″ shown in FIGS. 9-11. Thus, corresponding portions of the STT-RAM 200″′ are labeled similarly to the STT-RAMS 200/200′/200″. In particular, FIG. 12 depicts an embodiment of a portion of the write circuitry 246 that may be used with the preamplifier 245′ that is also shown in FIG. 12. Although not shown, the write circuitry 246 is used in conjunction with the storage cell 110 including selection transistor 112 and magnetic element 114. The bit lines 118, the common voltage plane 120, and word lines 116 for MAT 210″ are also shown. Although described in the context of the cell 110 and corresponding memory 100, the STT-RAM 200″ may incorporate the storage cell 110′ and remaining portions of the memory 100′ in other embodiments. In a write operation, the ENB signal going high turns off M4 and isolates the pre-amplifier circuit 245′ from the write driver 246. The write driver 246 is turned on by ENW going high and data is driven by GWRL (global write line). In a read operation, ENW goes low to tri-state the write driver 246. In addition, ENB goes high to reconnect the read circuitry 245′. Note that ENB is an inverted signal of ENW, or vice versa.

The magnetic memory 200″′ may share the benefits of the memories 100, 100′, 100″, 200, 200′, and 200″. Thus, because of the use of the preamplifier 245, there may be little or no read penalty. More specifically, as discussed above, a lower read current may be used within the MATs 210/210′/210″, amplified by the preamplifier 245′, and the amplified current may be provided to the sense amplifier 270 for determination of the state of the storage cell being read. Consequently, performance may be improved.

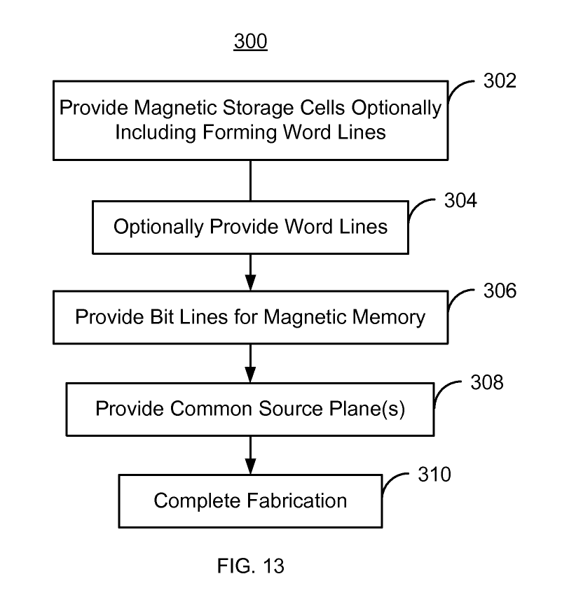

FIG. 13 depicts an exemplary embodiment of a method 300 for providing a magnetic memory. For clarity, the method 300 is described in context of the memory 100 in FIG. 4. However, in alternate embodiments, the method 300 may be used for other memories 100′, 200, 200′, 200″, and/or 200″′. In addition, the method 300 is described in the context of particular steps. However, steps may be combined, omitted, interleaved, and/or performed in another sequence.

The magnetic storage cells 110 are provided, via step 302. Step 302 includes providing the selection transistors 114 and magnetic elements 112. In addition, step 302 may include arranging in the magnetic storage cells 110 in MATs 210/210′/210″. Further, in an embodiment where the word lines 116 are, for example, polysilicon lines that also form part of the gates of the selection transistors 114, step 302 may include forming the word lines. The word lines 116 are optionally provided, via step 304. The word lines are provided in step 304 if they are not provided as part of providing the selection transistor in step 302. Because the word lines 116 may reside closer to the substrate in the magnetic memory than the magnetic elements 112, steps 302 and 304 may be interleaved. The bit lines 118 are provided, via step 306. At least one common source plane 120 is provided, via step 308. In some embodiments, a single common source plane for all magnetic storage cells 110, for example in all MATs 210/210′/210″ is provided. In other embodiments, multiple common source planes 120 may be provided. For example, each common source plane 120 may correspond to one or more of the MATs 210/210′/210″. Fabrication of the magnetic memory 100/200/200′/200″/200″′ may be completed, via step 310. Thus, other portions of the STT-RAMS 200/200′/200″ may be fabricated.

Using the method 300, the memory 100, 100′, 100″, 200, 200′, 200″, and/or 200″′ may be provided. Consequently, the benefits of the hierarchical architecture of the memories 100, 100′, 100″, 200, 200′, 200″, 200″′ might be achieved.

A method and system for a magnetic memory has been disclosed. The method and system has been described in accordance with the embodiments shown, and there could be variations to the embodiments, and any variations would be within the spirit and scope of the present invention. Accordingly, many modifications may be made by one of ordinary skill in the art without departing from the spirit and scope of the appended claims.

We claim:

1. A magnetic memory comprising:
a plurality of magnetic storage cells, each of the plurality of magnetic storage cells including at least one magnetic element and at least one selection device coupled with the at least one magnetic element, the at least one magnetic element being programmable using at least one write current driven through the at least one magnetic element;
a plurality of bit lines corresponding to the plurality of magnetic storage cells;
a plurality of word lines corresponding to the plurality of magnetic storage cells;
a common voltage plane coupled with the plurality of memory cells, the at least one write current flowing between the common voltage plane, the at least one magnetic element, and at least one of the plurality of bit lines.

2. The magnetic memory of claim 1 wherein the common voltage plane is connected with the at least one selection device and the bit line is connected with the at least one magnetic element.

3. The magnetic memory of claim 1 wherein the common voltage plane is connected with the at least one magnetic element and the bit line is connected with the at least one selection device.

4. The magnetic memory of claim 1 wherein the common voltage plane is biased at a fraction of a supply voltage.

5. The magnetic memory of claim 4 wherein the fraction of the supply voltage is one-half of the supply voltage.

6. The magnetic memory of claim 5 wherein a bit line of the plurality of bit lines is driven to the supply voltage to write the at least one magnetic element of a corresponding storage cell of the plurality of storage cells to a first state and the bit line is driven to a voltage that is less than or equal to zero volts to write the at least one magnetic element of the corresponding storage cell to a second state.

7. The magnetic memory of claim 1 wherein the plurality of bit lines are perpendicular to the plurality of word lines.

8. The magnetic memory of claim 1 wherein the plurality of bit lines are parallel to the plurality of word lines.

9. The magnetic memory of claim 1 wherein the plurality of bit lines and the at least one magnetic element reside between common voltage plane and the at least one selection device.

10. The magnetic memory of claim 1 wherein the plurality of magnetic storage cells, the plurality of word lines, and the plurality of bit lines are arranged in a plurality of memory array tiles (MATs), the memory array further comprising:
intermediate circuitry for controlling read operations and write operations within the plurality of MATs;
a plurality of global bit lines, each of the global bit lines corresponding to a first portion of the plurality of MATs and being coupled with a portion of the plurality of bit lines for the first portion of the plurality of MATS;
a plurality of global write lines, each of the global write lines corresponding to a second portion of the plurality of MATs and being coupled with a portion of the plurality of word lines for the second portion of the plurality of MATs; and
global circuitry for selecting and driving a portion of the plurality of global bit lines and a portion of the plurality of global write lines for the read operations and the write operations.

11. The magnetic memory of claim 10 wherein the intermediate circuitry further includes:
a plurality of intermediate drive/sense circuitry including a plurality of intermediate read drivers and a plurality of write drivers, each of the plurality of intermediate read drivers for controlling read operations in a third portion of the plurality of MATs, each of the plurality of write drivers for driving the write operations in a fourth portion of the plurality of MATs;
local decoding circuitry for selecting at least one selected MAT of the plurality of MATs and at least one of the storage cells in the at least one selected MAT

12. The magnetic memory of claim 11 wherein each of the plurality of intermediate read drivers further includes:
at least one preamplifier for amplifying a read signal from the portion of the plurality of MATs to provide an amplified read signal.

13. The magnetic memory of claim 12 wherein the at least one preamplifier further includes:
at least one current mirror preamplifier.

14. The magnetic memory of claim 1 wherein at least a portion of the plurality of storage cells includes a single transistor and a single magnetic element.

15. A magnetic memory comprising:
a plurality of memory array tiles (MATs), each of the plurality of MATs including a plurality of magnetic storage cells, a plurality of bit lines, and a plurality of word lines, each of the plurality of magnetic storage cells including at least one magnetic element and at least one selection device, the at least one magnetic element being programmable using at least one write current driven through the at least one magnetic element, the plurality of bit lines and the plurality of word lines corresponding to the plurality of magnetic storage cells;
a common voltage plane coupled with the plurality of memory cells, the at least one write current flowing between the common voltage plane, the at least one magnetic element, and at least one of the plurality of bit lines, the common voltage plane being biased at substantially one-half of a supply voltage, the plurality of bit lines and the at least one magnetic element residing between the at least one selection device and the common voltage plane;
intermediate circuitry for controlling read operations and write operations within the plurality of MATs;
a plurality of global bit lines, each of the global bit lines corresponding to a first portion of the plurality of MATs and being coupled with a portion of the plurality of bit lines for the first portion of the plurality of MATS;
a plurality of global write lines, each of the global write lines corresponding to a second portion of the plurality of MATs and being coupled with a portion of the plurality of word lines for the second portion of the plurality of MATs; and
global circuitry for selecting and driving a portion of the plurality of global bit lines and a portion of the plurality of global write lines for the read operations and the write operations.

16. A method for providing magnetic memory comprising:
providing a plurality of magnetic storage cells, each of the plurality of magnetic storage cells including at least one magnetic element and at least one selection device coupled with the at least one magnetic element, the at least one magnetic element being programmable using at least one write current driven through the at least one magnetic element;
providing a plurality of bit lines corresponding to the plurality of magnetic storage cells;
providing a plurality of word lines corresponding to the plurality of magnetic storage cells;
providing a common voltage plane coupled with the plurality of memory cells, the at least one write current flowing between the common voltage plane, the at least one magnetic element, and at least one of the plurality of bit lines.

17. The method of claim 16 wherein the fraction of the supply voltage is one-half of the supply voltage.

18. The method of claim 17 wherein the step of providing the plurality of bit lines further includes configuring each of the plurality of bit lines to be driven to the supply voltage to write the at least one magnetic element of a corresponding storage cell of the plurality of storage cells to a first state and to be driven to a voltage that is less than or equal to zero volts to write the at least one magnetic element of the corresponding storage cell to a second state.
